(19) United States
(12) Patent Application Publication
(10) Pub. No.: US 2011/0003470 A1
(43) Pub. Date: Jan. 6, 2011

(54) METHODS AND STRUCTURES FOR A VERTICAL PILLAR INTERCONNECT

(75) Inventors: Guy F. Burgess, Phoenix, AZ (US); Anthony Curtis, Phoenix, AZ (US); Michael E. Johnson, Tempe, AZ (US); Gene Stout, Phoenix, AZ (US); Theodore G. Tessier, Phoenix, AZ (US)

Correspondence Address: GREENBERG TRAURIG LLP (LA), 2450 COLORADO AVENUE, SUITE 400E, INTELLECTUAL PROPERTY DEPARTMENT, SANTA MONICA, CA, 90404, US

(73) Assignee: FlipChip International, LLC, Phoenix, AZ (US)

(21) Appl. No.: 12/828,003

(22) Filed: Jun. 30, 2010

Related U.S. Application Data
(60) Provisional application No. 61/222,839, filed on Jul. 2, 2009.

(51) Int. Cl. H01L 21/768

(52) U.S. Cl. 438/614; 257/E21.589

(57) ABSTRACT

In wafer-level chip-scale packaging and flip-chip packaging and assemblies, a solder cap is formed on a vertical pillar. In one embodiment, the vertical pillar overlies a semiconductor substrate. A solder paste, which may be doped with at least one trace element, is applied on a top surface of the pillar structure. A reflow process is performed after applying the solder paste to provide the solder cap.

### RELATED APPLICATIONS

This application is a non-provisional application claiming priority to and benefit under 35 U.S. Sec. 119(e) of prior U.S. Provisional Application Ser. No. 61/222,839, filed Jul. 2, 2009 (titled METHOD FOR BUILDING CU PILLAR INTERCONNECT, by Guy Burgess et al.), which is hereby incorporated by reference in its entirety herein.

### FIELD

The present disclosure generally relates to a structure, apparatus, system, and method for semiconductor devices, and more particularly to a structure, apparatus, system, and method for electronic wafer-level chip-scale packaging and flip-chip packaging and assemblies.

### BACKGROUND

Copper pillar bumps, which are one type of vertical interconnect technology, can be applied to semiconductor chips or other microelectronic device bond pads via copper pillar bumping technologies that are known to those familiar with the art. The copper pillar bumps are placed on the chips/devices while the chips/devices are still in their wafer form. All solder-based flip-chip and/or chip scale package (CSP) style interconnects (bumps) require suitable under bump metallurgy (UBM) to act as adhesion layers/diffusion barriers between the wafer/substrate metallization and the solder bump itself. Pillar bumps (copper, gold, or other metals/alloys) have the potential to be used as functional UBMs, provided that reliable/manufacturable methods are used to form the solder bumps on wafers.

A copper pillar bump offers a rigid vertical structure when compared to a typical solder bump or CSP interconnect. In applications where control of the standoff between two surfaces, such as a device and its associated substrate, is required, the copper pillar bump acts as a fixed standoff to control that distance, while the solder performs the joint connection between the two surfaces. Controlling this standoff is critical to the overall system performance and reliability. Copper (Cu) pillar bump structures also offer improved thermal transfer and resistivity compared to equivalent flip-chip or CSP solder bump structures.

Copper (Cu) pillar bump structures have the potential to be a cost-effective, reliable interconnect option for certain markets in the microelectronics industry. However, reliable and low cost manufacturable methods are needed for building these versatile fixed standoff bump structures. Most pillar bump manufacturing methods use a photo-definable mask material to electroplate the Cu pillar structure followed by an electroplated solder. Plating the solder is a slow, expensive process that requires considerable process control and strictly limits the solder to a narrow offering of monometallic or binary solder alloys. Typically, electroplating more than a binary solder alloy to form the solder portion of the pillar bump is very difficult to control in a manufacturing environment. In the semiconductor industry, however, the use of various multiple element alloys or alloys doped with trace elements is desirable to improve the reliability of the interconnect for targeted applications or end-uses.

### DRAWINGS

These and other features, aspects, and advantages of the present disclosure will become better understood with regard to the following description and accompanying drawings in which like references indicate similar elements.

FIG. 1 illustrates a cross-sectional view of a portion of a wafer substrate 102 with input/output (I/O) bond pads 104, in accordance with at least one embodiment of the present disclosure. This view shows a passivation layer 103 and a dielectric layer 105. In one embodiment, dielectric layer 105 is a polymer layer. This view also shows a deposited plating seed layer 106 and a dual-purpose photoresist masking material 108 following patterned exposure and development. This forms the necessary apertures 110 for subsequent copper (or other metal) plating and solder paste print processes, as described below.

FIG. 2 illustrates the cross-sectional view following copper plating of pillar 202 with the upper portion 204 of the aperture 110 reserved for solder paste printing, in accordance with at least one embodiment of the present disclosure.

FIG. 3 illustrates the cross-sectional view after the printing of the solder paste 300 into the apertures. This affords the use of multi-element solder alloys with options of various trace elements to improve the reliability of the solder, in accordance with at least one embodiment of the present disclosure.

FIG. 4 illustrates the cross-sectional view following solder reflow where the solder paste has formed hemispherical solder bumps 402 on top of copper (Cu) pillars 202, in accordance with at least one embodiment of the present disclosure.

FIG. 5 illustrates the cross-sectional view of the completed part following the strip removal of the photoresist material and the etch removal of the non-pillar plated portion of seed layer 106, in accordance with at least one embodiment of the present disclosure.

FIG. 6 illustrates the cross-sectional view of an assembled copper (Cu) pillar bump with a corresponding board 606 or other substrate, in accordance with at least one embodiment of the present disclosure. Solder cap 402 provides solder connection 602 after assembly to pad 604 on board or substrate 606. An underfill or overmolding 605 is provided during assembly.

FIG. 7 illustrates a variation of the method of this disclosure as used in an alternative embodiment with one of many options using multiple layers of photoresist (108, 702) and/or other resist-type materials to create variations in the columnar structure and in the solder volume in order to achieve the desired pillar and solder dimensional parameters, in accordance with at least one embodiment of the present disclosure. In one specific embodiment, photoresist layer 702 has a number of apertures, with each aperture to define a dimension of a portion of solder paste 300 overlying a particular pillar 202. Each pillar 202 has a dimension defined by a respective one of a number of apertures in photoresist layer 108. As a result, solder paste 300 has a greater lateral dimension than pillar 202. In other embodiments, the height and aperture sizes in each of the photoresist layers 108 and 702 may be varied to adjust the relative volumes of pillar metal and overlying solder material as may be desired for a particular interconnect application.

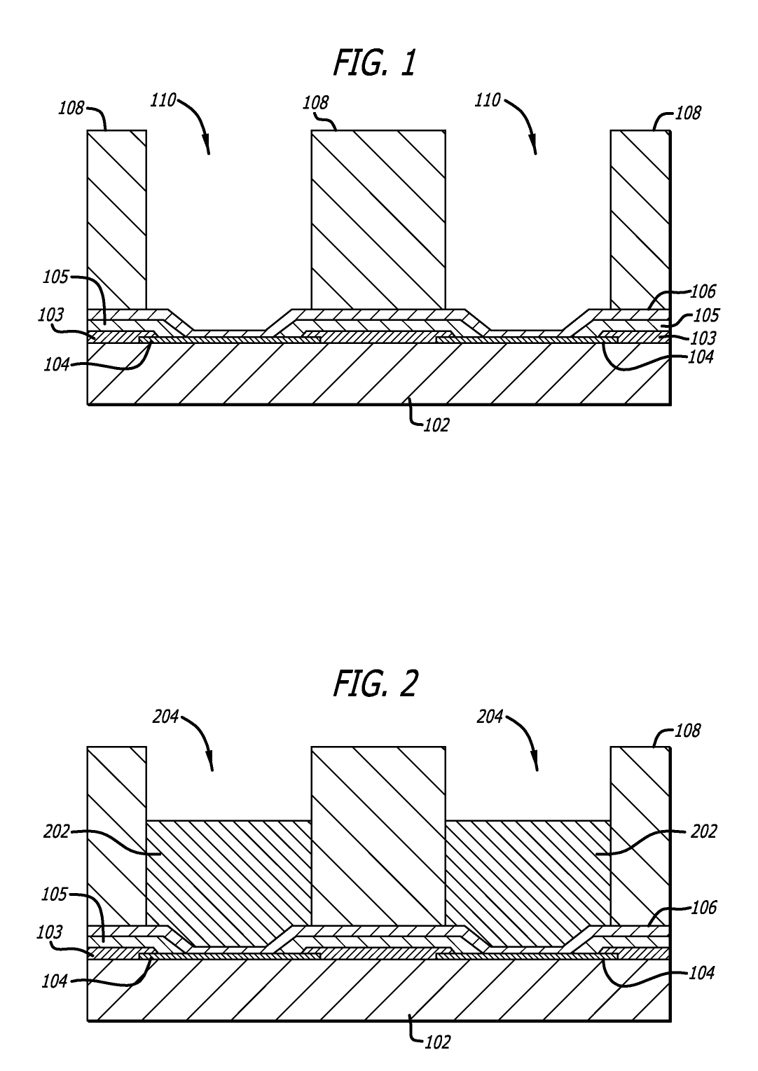

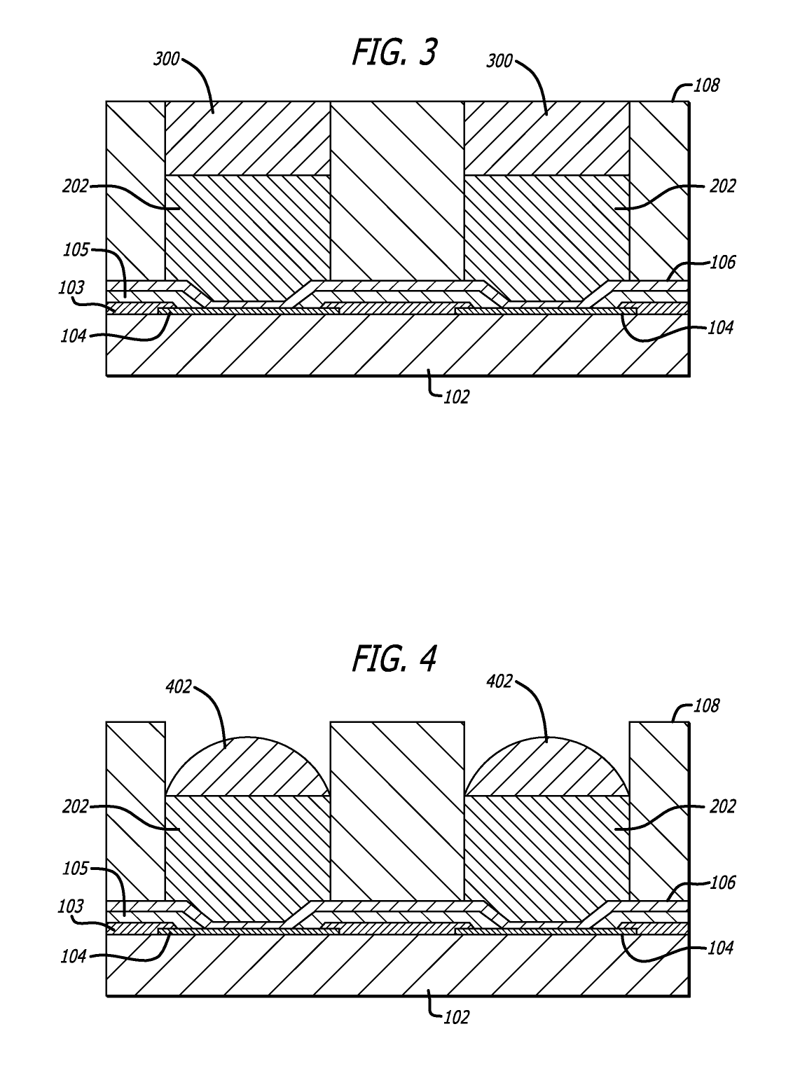

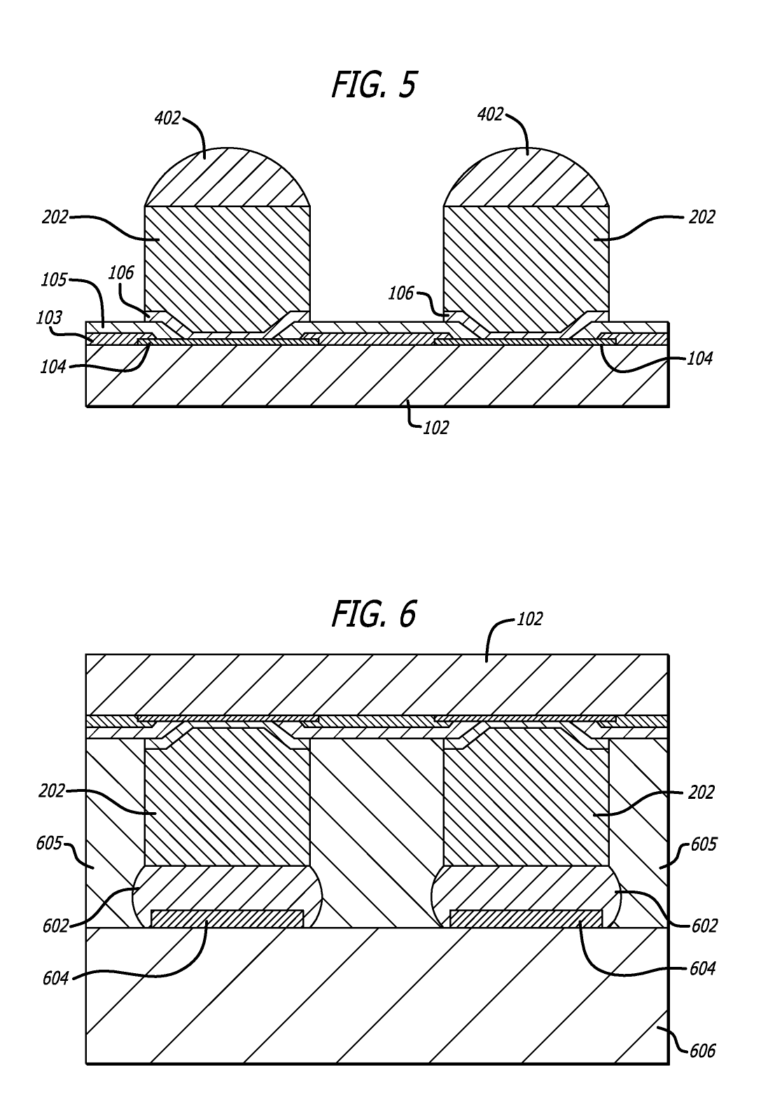

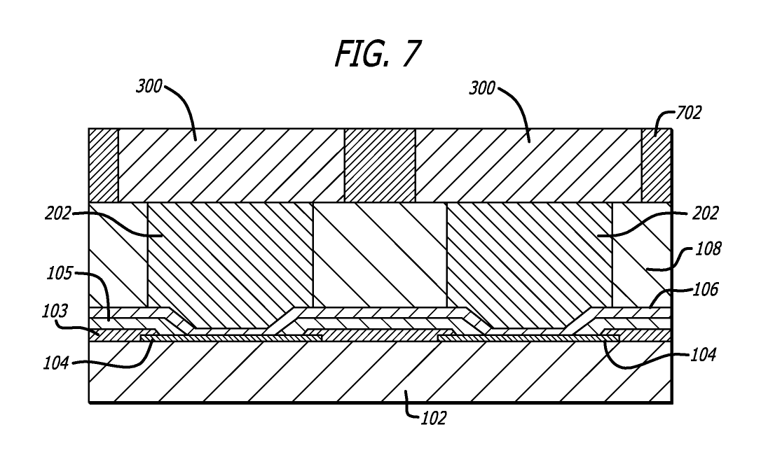

The exemplification set out herein illustrates particular embodiments, and such exemplification is not intended to be construed as limiting in any manner.

### DETAILED DESCRIPTION

In the following description, numerous details are set forth in order to provide a more thorough description. It will be apparent, however, to one skilled in the art, that the disclosed methods and structures may be practiced without these specific details. In the other instances, well-known features have not been described in detail so as not to unnecessarily obscure the disclosure.

In various embodiments discussed herein, this disclosure provides an enhanced solder-based wafer-bumping technology with variable height under bump metallizations (UBMs), thereby providing a functional vertical interconnect structure that can be used to connect a semiconductor chip or other microelectronic device to a circuit board, or other substrate for use in two-dimensional (2D) and three-dimensional (3D) packaging solutions.

A reliable and manufacturable method for forming solder caps 402 on vertical pillars 202 is disclosed. In one embodiment, a method is disclosed to provide a way to significantly simplify the manufacturing flow and reduce the cost of manufacturing vertical interconnection structures by the use of a dual-purpose photoresist process, which serves both as a plating mold and a subsequent solder paste in-situ stencil template. In another embodiment, a method is disclosed for printing various solder pastes on top of a vertical pillar structure followed by a subsequent reflow to form the solder cap 402. In yet another embodiment, a method is disclosed for using solder pastes that also includes the method of using various multiple-element alloys and trace elements within the solder paste that can enhance the reliability or performance of the solder cap 402.

In one or more embodiments, these methods apply to copper pillars 202 and other vertical interconnection schemes of various sizes and shapes including, but not limited to, formation of pillars 202 using the following metals: copper and its alloys, gold and its alloys, nickel and its alloys, and silver and its alloys. The copper (Cu) pillar 202 may also include a solder wettable cap finish (not shown) including, but not limited to: Ni, NiAu, NiPdAu, NiPd, Pd, and NiSn.

In some embodiments, these methods may be used to build copper (Cu) pillar bump structures attached to an input/output (I/O) bond pad 104 or as an attached structure off of a redistributed bond pad.

In some embodiments, a printed solder paste 300 is used, which permits an end product with a much broader range of solder alloys than prior methods using a plated solder. In one or more embodiments, the solder paste 300 is one of the following alloys/metals: SnPb alloys, SnPbCu alloys, SnAgCu alloys, AuGe alloys, AuSn alloys, AuSi alloys, SnSb alloys, SnSbBi alloys, PbSnSb alloys, PbInSb alloys, PbIn alloys, PbSnAg alloys, SnAg alloys, PbSb alloys, SnInAg alloys, SnCu alloys, PbAg alloys, PbSbGa alloys, SnAs alloys, SnGe alloys, ZnAl alloys, CdAg alloys, GeAl alloys, AuIn alloys, AgAuGe alloys, AlSi alloys, AlSiCu alloys, AgCdZnCu alloys, and AgCuZnSn alloys. Other solder paste materials may be used.

In some embodiments, this method also may include any solder sintering alloys deposited in the “in situ” aperture, such as Ag sintering material. Also, various embodiments employ a printed solder paste 300, which permits the option for an end product with various trace elements in the solder including, but not limited to, Bi, Ni, Sb, Fe, Al, In, and Pb. In alternative embodiments, solder paste 300 is a single metal solder. For example, the solder paste may be Sn. This single metal solder may be doped with one or more trace elements similarly as doping is described herein for solder alloys.

The resulting pillar 202 and solder cap 402 structure using these methods may have, for example, an overall height ranging between 5 and 400 microns (μm) and a pitch as low as 10 microns (μm).

The x and y dimensional limits (i.e., vertical and horizontal limits) of the pillars 202 produced using these methods may have, for example, pillars 202 as small as 5 microns (μm) and up to 2.0 millimeters (mm). In other embodiments, pillars 202 produced using these methods may have x and y dimensional limits up to 5.0 millimeters (mm).

In one or more embodiments, the method of the present disclosure for forming solder bumps using solder paste on vertical interconnect structures, with various iterations, is as follows:

Step 1. A seed layer 106 of metal is deposited by conventional methods (i.e., sputtering, evaporation, electroless plating, etc.) to provide a continuous seed layer 106 for electrochemical plating.

In one embodiment, dielectric layer 105 (e.g., a polymer layer) has been previously formed over passivation layer 103. Dielectric layer 105 has been previously patterned to form openings to expose respective portions of bond pads 104 so that portions of seed layer 106 may contact the top surface of each bond pad 104.

Step 2. A photoresist layer 108 or other resist type material is applied over the entire surface of the wafer/substrate 102. This can be achieved by dry film lamination, or spin or spray coating methods.

In other embodiments, photoresist layer 108 may be a photoresist stack formed by the application of two or more photoresist layers, each having an aperture of a common size (i.e., the aperture size of the photoresist stack). In one embodiment, these two or more photoresist layers are developed in the same processing step. In an alternative embodiment, each photoresist layer may be developed independently.

Step 3. The photoresist layer 108 is, in this embodiment, generally defined by ultraviolet (UV) exposure through an appropriate photomask based on the design, but the creation of the aperture is not limited to UV exposure/development and may include, but is not limited to, laser ablation, dry etch, and/or lift-off processes.

For alternate embodiments of this method, multiple layers of photoresist materials or other resist type materials can be applied to form varied aperture heights and apertures sizes within the same resist stack that can facilitate varied columnar structures and varied solder volumes printed on top of the columnar structure.

Step 4. The photoresist layer(s) 108 covering the seed layer 106 is developed, or otherwise opened, forming open “in-situ” apertures 110 for the plating of pillar 202 and subsequent solder paste printing.

Step 5. Pillars 202 are electroplated onto the seed metal layer 106 surface in the apertures 110 formed in the photoresist layer 108.

Step 6. Solder paste 300 is printed into upper portions 204 of the “in-situ” apertures 110 in the photoresist stencil with the solder paste 300 covering the top of the copper pillars 202. The overall depth of the printed solder paste 300 can range, for example, between 2 and 200 microns (μm). Alternatively, a metal stencil could also be used to further define the area where solder can be applied over the pillar bump structure both in and above the “in-situ” photoresist material.

Step 7. The wafer or other substrate 102 with printed solder paste 300 in place is then reflowed and cooled, forming solder caps 402 on top of the copper pillars 202.

Step 8. The “in-situ” photoresist stencil material is stripped away or otherwise removed.

Step 9. The un-plated seed layer 106 is selectively etched away, leaving behind individual pillars 202 capped with solder.

Step 10. A second reflow may be performed on the wafer or other substrate to optimize the bump shape. Also, a coining or flattening process can be used to further reduce bump-to-bump resolution beyond that possible with copper (Cu) pillar technology developed as part of the prior art.

Steps 1-10 are all performed using processing methods and tool sets known to those experienced in the art with photo-imaging, plating, and solder bumping processes. In alternative embodiments, the above process steps may be performed without the use of dielectric layer 105. More specifically, in these alternative embodiments dielectric layer 105 is never formed and is not present in the final structure. Seed layer 106 is formed (e.g., by deposition) directly onto passivation layer 103 and bond pads 104.

It is noted that plating has been previously used by others to form solder-over-pillar interconnect structures. APS, Casio, and RFMD have plated a copper pillar onto an interconnect pad on the device, and then applied a cap of electroplated solder to the top of the pillar to be used for the interconnect material between the device and the joining substrate. Prior patents of APS include the following patents: U.S. Pat. No. 6,732,913, U.S. Pat. No. 6,681,982, and U.S. Pat. No. 6,592,019. Also, FlipChip International (FCI) has previously used an “in situ” photoresist material to define the solder opening over a previously-formed UBM (not defined by the same photoresist layer). However, none of these prior methods use a dual-purpose photoresist process for plating and printing the solder paste as described herein.

Some embodiments of this disclosure may be desirably used to provide an interconnect solution for higher-power applications and controlled collapse for consistent standoff in flip-chip applications, especially for System-in-Package applications where maximum component density and the avoidance of “keep-out” areas for underfilling is desirable.

Various other embodiments of the disclosure above may include the following methods and structures (numbered below merely for ease of reference):

1. A method of using solder pastes doped with any variety of trace elements in the solder alloy for any existing or new method of forming copper pillars and specifically to “topping off” the copper pillar with doped solder pastes.

2. A method of using solder pastes of any variety alloy for any existing or new method of forming copper pillars and specifically to “topping off” the copper pillar with solder pastes to form solder caps.

3. A method for forming solder capped vertical pillar structures based on the use of a dual-purpose “in-situ” photoresist process or other type resist materials where the resist serves as both a plating mold and subsequent solder paste stencil template.

4. A method for forming solder-capped vertical pillar structures based on the printing of solder paste alloys on top of the vertical pillar structure followed by a subsequent reflow process. The solder pastes can be comprised of solder particles of any size range including nano-particles.

5. In one embodiment, this method for forming solder capped vertical pillar structures based on printing solder paste alloys is further enhanced by the use of multi-element solder paste alloys that are not easily accomplished by plating methods as listed in the prior art. These multi-element solder alloys can enhance the reliability or performance of the solder and/or intermetallics for vertical interconnects.

6. A method for forming solder capped vertical pillar structures based on the printing of solder paste alloys doped with various trace elements in the solder alloy (such as, but not limited to, Bi, Ni, Sb, Fe, Al, In, and Pb) on top of the vertical pillar structure followed by a subsequent reflow process. These doped solder alloys can enhance the reliability or performance of the solder and/or intermetallics for vertical interconnects.

7. The methods of using a dual purpose photoresist process and the printing of solder pastes atop the pillar structure offer a lower cost of manufacturing than conventional plated solder methods due to the faster process time and reduced process controls necessary for solder printing versus solder plating.

8. Alternate embodiments of the dual-purpose resist method can include multiple layers of resist material with one or more photo exposures or other methods of opening the resist apertures that can be applied to form varied aperture heights and aperture sizes within the same resist stack that can facilitate varied columnar structures and varied solder volumes printed on top of the columnar structure.

9. These types of varied solder-capped columnar structures can be incorporated into 3D wafer level packaging applications where variable height Z-axis interconnects are required.

In one embodiment, a method includes forming first and second vertical pillars each overlying a respective bond pad, wherein the respective bond pad overlies a semiconductor substrate, and the first and second pillars each have a different height; forming at least one photoresist layer having a first aperture and a second aperture; and applying solder on a top surface of each of the first and second pillars, wherein the solder on the first pillar is defined by the first aperture and the solder on the second pillar is defined by the second aperture.

10. The method of printing solder pastes on top of columnar pillar structures can not only be used within the apertures in the “in-situ” photoresist, but can also be accomplished with the use of a metal stencil where the paste is applied over the pillar bump structure in and above the “in-situ” photoresist material offering even more versatility for applying solder volume.

11. The method of using a dual purpose resist for manufacturing pillar bumps improves the overall pillar/solder height uniformity compared to conventional plating methods as listed in the prior art. As there are height uniformity differences across the substrate, following the plating of the copper (Cu) pillar portion of the structure, the printed solder helps planarize any height variation by filling the remaining depth of the “in-situ” aperture, thus accommodating any variation. For conventional pillar bump plating methods, the plated solder portion of the pillar would continue to extend any difference in height uniformity across the wafer or other substrate.

12. The process steps of applying one or more layers of a photoresist material or other resist type materials for eventual solder paste filling can also be performed after the formation of the vertical pillar.

13. The process steps of applying one or more layers of a photoresist material or other resist type material for eventual solder paste filling, or the use of a mechanical stencil to apply solder paste, can be performed after the vertical structure formation and a subsequent mechanical or chemical leveling of the copper (Cu) pillar structure. This would planarize the copper (Cu) pillars or other metal columnar structures before the solder paste is deposited.

14. These methods apply to copper pillar bump-like structures and other vertical interconnection schemes of various sizes and shapes including, but not limited to, the following metals: copper and its alloys, gold and its alloys, nickel and its alloys, and silver and its alloys. The copper (Cu) pillar may also include a solder-wettable cap finish including, but not limited to: Ni, NiAu, NiPdAu, NiPd, Pd, and NiSn.

15. These methods can construct various shaped vertical interconnects including, but not limited to, circular, rectangular, octagonal, etc.

In yet another embodiment, a method is provided, the method comprising forming first and second vertical pillars each overlying a respective bond pad, wherein the respective bond pad overlies a semiconductor substrate; forming at least one photoresist layer having a first aperture and a second aperture; applying solder on a top surface of each of the first and second pillars, wherein the solder on the first pillar is defined by the first aperture and the solder on the second pillar is defined by the second aperture; and performing a reflow to form a first solder cap on the first pillar and a second solder cap on the second pillar, wherein the combined height of the first pillar and first solder cap is greater than the combined height of the second pillar and second solder cap. In one embodiment, the at least one photoresist layer is a single photoresist layer or a multi-layer photoresist stack. In one embodiment, the combined height of the first pillar and first solder cap is greater than the combined height of the second pillar and second solder cap by at least about 5 microns.

Although certain illustrative embodiments and methods have been disclosed herein, it is apparent from the foregoing disclosure to those skilled in the art that variations and modifications of such embodiments and methods can be made without departing from the true spirit and scope of the disclosure.

1. A method, comprising:
forming a vertical pillar overlying a bond pad, wherein the bond pad overlies a semiconductor substrate; and
applying a solder paste on a top surface of the pillar, wherein the solder paste is defined by at least one photoresist layer.

2. The method of claim 1, wherein the pillar is defined by the at least one photoresist layer.

3. The method of claim 1, wherein:
the at least one photoresist layer has a first aperture to define the solder paste;
the pillar is defined by a second aperture in an additional photoresist layer;
the at least one photoresist layer is formed overlying the additional photoresist layer; and
the first aperture has a greater lateral dimension than the second aperture.

4. The method of claim 1, wherein the solder paste is a solder alloy or a single metal solder, and the solder paste is doped with at least one trace element.

5. The method of claim 4, wherein the at least one trace element is at least one of Bi, Ni, Sb, Fe, Al, In, and Pb.

6. The method of claim 1, wherein the solder paste is a multi-element solder alloy.

7. The method of claim 1, further comprising, subsequent to the applying the solder paste, performing a reflow so that a solder cap is formed on top of the vertical pillar.

8. The method of claim 1, wherein the vertical pillar is one of a plurality of vertical pillars, and further comprising, prior to applying the solder paste, planarizing the plurality of vertical pillars.

9. The method of claim 1, wherein the vertical pillar is one of a plurality of vertical pillars, and each of the plurality of vertical pillars corresponds to a variable height Z-axis interconnect.

10. The method of claim 1, wherein the vertical pillar is copper.

11. The method of claim 10, wherein the vertical pillar comprises a solder-wettable cap finish formed of one of Ni, NiAu, NiPdAu, NiPd, Pd, and NiSn.

12. The method of claim 1, wherein the vertical pillar is one of copper, a copper alloy, gold, a gold alloy, nickel, a nickel alloy, silver, and a silver alloy.

13. The method of claim 1, wherein the vertical pillar has a shape selected from one of the following: circular, rectangular, and octagonal.

14. The method of claim 1, wherein the solder paste is a solder alloy or a single metal solder.

15. The method of claim 1, further comprising, prior to forming the vertical pillar, forming a seed layer overlying the bond pad.

16. The method of claim 15, further comprising, prior to forming the vertical pillar, forming the at least one photoresist layer overlying the seed layer.

17. The method of claim 1, further comprising:
prior to forming the vertical pillar, forming a dielectric layer overlying the bond pad and providing an opening in the dielectric layer to expose a portion of the bond pad; and
forming a seed layer overlying the dielectric layer.

18. The method of claim 17, wherein the dielectric layer is a polymer layer.

19. The method of claim 1, further comprising defining an area, using a metal stencil, in which a portion of the solder paste is applied over the vertical pillar above the at least one photoresist layer.

20. The method of claim 1, wherein the at least photoresist layer is one of: a single photoresist layer; and a plurality of photoresist layers, each having an aperture of a common size.

21. The method of claim 1, wherein the applying the solder paste comprises printing the solder paste.

22. The method of claim 1, wherein the solder paste is Sn.

23. The method of claim 2, further comprising, subsequent to the applying the solder paste, performing a reflow so that a solder cap is formed on top of the vertical pillar.

24. A method, comprising:
forming a vertical copper pillar overlying a bond pad, wherein the bond pad overlies a semiconductor substrate;
applying a solder paste on top of the copper pillar, wherein the solder paste is defined by at least one photoresist layer, and the solder paste is doped with at least one trace element; and
performing a reflow so that a solder cap is formed from the solder paste.

25. The method of claim 24, wherein the vertical copper pillar comprises a solder-wettable cap finish formed of one of Ni, NiAu, NiPdAu, NiPd, Pd, and NiSn.

26. The method of claim 24, further comprising:
prior to forming the vertical copper pillar, forming a seed layer overlying the bond pad; and
prior to forming the vertical copper pillar, forming the at least one photoresist layer overlying the seed layer.

27. The method of claim 24, wherein the solder paste is Sn.

28. The method of claim 24, further comprising:
prior to forming the vertical copper pillar, forming a dielectric layer overlying the bond pad and providing an opening in the dielectric layer to expose a portion of the bond pad; and
forming a seed layer overlying the dielectric layer.

29. The method of claim 24, wherein a passivation layer overlies the semiconductor substrate and has an opening to expose the bond pad, the method further comprising, prior to forming the vertical copper pillar, depositing a seed layer directly onto the passivation layer and the bond pad.

30. A method, comprising:
forming first and second vertical pillars each overlying a respective bond pad, wherein the respective bond pad overlies a semiconductor substrate;
forming at least one photoresist layer having a first aperture and a second aperture;
applying solder on a top surface of each of the first and second pillars, wherein the solder on the first pillar is defined by the first aperture and the solder on the second pillar is defined by the second aperture; and
performing a reflow to form a first solder cap on the first pillar and a second solder cap on the second pillar, wherein the combined height of the first pillar and first solder cap is greater than the combined height of the second pillar and second solder cap.

31. The method of claim 30, wherein the at least one photoresist layer is a single photoresist layer or a multi-layer photoresist stack.

32. The method of claim 30, wherein the combined height of the first pillar and first solder cap is greater than the combined height of the second pillar and second solder cap by at least about 5 microns.
